(19) United States
(12) Patent Application Publication
(10) Pub. No.: US 2008/0142079 A1
(43) Pub. Date: Jun. 19, 2008

(54) Photovoltaic cell

(75) Inventors: Ching Ting, Hsinchu (TW); Hsin-Fei Meng, Taipei County (TW); Yi-Chun Chen, Hsinchu City (TW); Jeng-Liang Han, Kaohsiung City (TW); Bao-Tsan Ko, Pingtung County (TW); Ching-Yen Wei, Taipei City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/730,856

(22) Filed: Apr. 4, 2007

(30) Foreign Application Priority Data
Dec. 15, 2006 (DE) 10 2006 059 369.3

(51) Int. Cl. H01L 31/00

(52) U.S. Cl. 136/263

(57) ABSTRACT

The invention discloses a photovoltaic cell with a high photocurrent. The photovoltaic cell comprises a first electrode, a second electrode, a photoactive layer between the first and second electrodes, and a polar organic layer between the photoactive layer and at least one of the first and second electrodes.

### BACKGROUND OF THE INVENTION

1. Field of the Invention

The invention relates to a photovoltaic cell, and in particular to a photovoltaic cell having a high photocurrent.

2. Description of the Related Art

Photosensitive optoelectronic devices convert electromagnetic radiation into electricity. Solar cells, also known as photovoltaic (PV) devices, are used to generate electrical power from ambient light. Photovoltaic devices are used to drive power consuming loads to provide, for example, lighting, heating, or to operate electronic equipment such as computers or remote monitoring or communications equipment. These power generation applications often involve the charging of batteries or other energy storage devices so that equipment operation may continue when direct illumination from the sun or other ambient light sources is not available.

Traditionally, photosensitive optoelectronic devices have been constructed of a number of inorganic semiconductors, e.g., crystalline, polycrystalline and amorphous silicon, gallium arsenide, cadmium telluride and others. Solar cells are characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs.

Organic photovoltaic cells have many potential advantages when compared to traditional silicon-based devices. Organic photovoltaic cells are light weight, economical in materials use, and can be deposited on low cost substrates, such as flexible plastic foils. However, organic photovoltaic devices typically have relatively low quantum yield (the ratio of photons absorbed to carrier pairs generated, or electromagnetic radiation to electricity conversion efficiency), being on the order of 5% or less. Different approaches to increase the efficiency have been demonstrated, including use of doped organic single crystals, conjugated polymer blends, and use of materials with increased exciton diffusion length.

There remains a need in the art to enhance photo-electric conversion efficiency of organic photovoltaic cells.

### BRIEF SUMMARY OF THE INVENTION

A general object of the invention to provide a photovoltaic cell with improved photo-electric conversion efficiency. To this end, the invention provides a photovoltaic cell capable of operating with a high photocurrent density.

According to one aspect of the invention, there is provided a photovoltaic cell comprising a first electrode, a second electrode, a photoactive layer between the first and second electrodes, and a polar organic layer between the photoactive layer and at least one of the first and second electrodes.

According to another aspect of the invention, there is provided a photovoltaic cell, comprising a first electrode, a second electrode, a photoactive layer between the first and second electrodes, and an organic layer between the photoactive-layer and at least one of the first and second electrodes, wherein the organic layer comprises a surface opposite to the photoactive layer, possessing polar functionality pointing towards at least one of the electrodes.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross-sectional view of an embodiment of a photovoltaic cell.

### REFERENCE NUMERALS IN THE DRAWINGS

10 substrate
20 bottom electrode
30 smoothing layer
40 photoactive layer
50 polar organic layer
60 top electrode

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

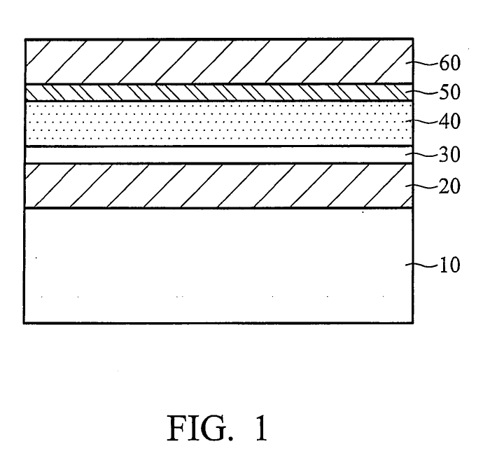

Referring now to FIG. 1, which is a schematic cross section illustrating a photovoltaic cell according to an embodiment of the invention. The photovoltaic cell of the invention features a polar organic material 50 interposed between a photoactive layer 40 and at least one of the electrodes 20, 60. It was found that the presence of the polar material would significantly increase the photocurrent density by as high as 50%. Although the detailed mechanism is not yet ascertained, it is believed to be caused, at least partially, by the interfacial dipole generated by the polar material. It is believed that the interfacial dipole facilitates the transportation of the charge carrier, thus increasing the photocurrent density.

Each component constituting the photovoltaic cell of the invention is now described in greater detail. In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers.

As shown in FIG. 1, the photovoltaic cell is supported by or deposited on a suitable substrate 10 such as a glass, plastic or metal. The substrate 10 can be a rigid support, such as, for example, glass or quartz or the like. Alternatively, the substrate 10 can be formed from a mechanically-flexible material, such as a flexible polymer. Examples of polymers that can be used to form a flexible substrate include polyethylene naphthalates (PEN), polyethylene terephthalates (PET), polyamides, polymethylmethacrylate, polycarbonate, and/or polyurethanes. Flexible substrates can facilitate continuous manufacturing processes such as web-based coating and lamination. Not only insulating substrates but also conductive substrates of metals such as titanium, aluminum, copper and nickel can be employed. The thickness of the substrate 10 can vary as desired.

A bottom electrode 20 is disposed on a surface of the substrate 10. In preferred embodiments, the bottom electrode 20 is transparent so that radiation can pass through it to the photoactive layer 40. Examples of transparent materials suitable for forming such an electrode include certain metal oxides, typically indium tin oxide (ITO), tin oxide, and a fluorine-doped tin oxide, though other metal oxides and doped metal oxides may be used. The bottom electrode 20 can be formed by the use of conventional methods, such as vapor-deposition or sputtering. The thickness of the bottom electrode may be, for example, between about 50 nm and 500 nm. The bottom electrode 20 generally has a comparatively rough surface structure, so that it is preferably covered with a smoothing layer 30 made of polymer. An exemplary material for this layer comprises a film of polyethylene dioxythiophene:polystyrene sulfonate (PEDOT:PSS), though other materials may be used. The PEDOT:PSS layer can be spin-coated to planarize the bottom electrode 20, whose rough surface could otherwise result in shorts. The smoothing layer 30 may have an adjustable thickness ranging from about 10 nm to about 100 nm, for example. In addition, the PEDOT:PSS layer also functions as a hole injection layer (HIL) that promotes the hole injection into the electrode 20. Accordingly, the PEDOT:PSS may be replaced by other doped-conductive polymers as long as they provide a suitable workfunction that promotes the hole injection into the electrode 20.

Overlying the smoothing layer 30 is a photoactive layer 40 made of at least two components, specifically a conjugated polymer component as an electron donor and a fullerene component as an electron acceptor. Examples of typical conjugated polymers include, but are not limited to derivatives of polyacetylene (PA), polyisothianaphthene (PITN), polythiophene (PT), polypyrrol (PPr), polyfluorene (PF), poly(p-phenylene) (PPP), and poly(phenylene vinylene) (PPV). Examples of acceptors in donor/acceptor polymer mixtures include but are not limited to poly(cyanophenylenevinylene), fullerenes such as C60 and its functional derivatives (such as PCBM) and organic molecules, organometallic molecules or inorganic nanoparticles (such as, for example, CdTe, CdSe, CdS, CIS). A preferred material for the photoactive layer 40 comprises a mixture of P3HT:PCBM (poly(3-hexylthiophene):[6,6]-phenyl C₆₁-butyric acid methyl ester).

The above two components are mixed with a solvent and applied as a solution onto the smoothing layer 30 by, for example, spin coating. Other common coating methods such as spray coating, screen-printing, and inkjet printing, may be employed. The photoactive layer may have a thickness of, for example, 50 nm to few μm depending on the application method. In addition, the photoactive layer 40 can also be constructed in two separate layers in which the donor is spatially separated from the acceptor (e.g., PT/C60 or PPV/C60).

According to an important feature of the invention, before depositing a top electrode (or counter electrode) 60, a polar organic layer 50 is provided on the photoactive layer 40. The polar organic layer 50 is preferably made of polar polymers possessing at least one of the following polar functional groups: hydroxyl, carbonyl, carboxyl, mercapto, amino, halo, cyano, alkoxy, epoxy, and sulfonyl. Examples of suitable polar polymers include, but are not limited to, polycarbonate, poly(acrylic acid), poly(methacrylic acid), polyoxides, polysulfides, polysulfones, polyamides, polyesters, polyurethanes, polyimides, poly(vinyl acetate), poly(vinyl alcohol), poly(vinyl chloride), poly(vinyl pyridine), poly(vinyl pyrrolidone), celluloses (including modified celluloses), copolymers thereof, combinations thereof, and various polyolefin copolymers containing relatively high proportions (>50 molar percent) of a polar comonomer. More preferred polar polymers are those having a high dielectric constant (k) of above 3. In preferred embodiments, the polar organic layer may result in at least 20% increase in photocurrent, and in more preferred embodiments, it may result in as high as a 50% increase in photocurrent, although no lower limit is generally imposed on the improvement.

The polar organic layer 50 may be formed by spin coating a polymer solution containing the above polar polymer. Other common coating techniques such as spray coating, screen-printing, and inkjet printing, may be employed. As the polar polymer is coated on the photoactive layer 40 which has a non-polar surface, the polar functionalities of the polar polymer are expected to predominately reside at the opposite (i.e., upper) surface when formed into a film. These polar functionalities point towards a top electrode which will be formed subsequently and provide an interfacial dipole therebetween. It is considered that the interfacial dipole enhances the mobility of the charge carrier and increases the photocurrent density as a result. Experimental study shows that the thickness of the polar organic layer 50 plays a crucial role in controlling the photocurrent density. The polar organic layer 50 is preferably deposited to a thickness of about 0.1-20 nm, more preferably below 10 nm. Otherwise, the beneficial influence of the polar organic layer may be lost due to the resistivity of the polar organic layer as a bulk. It should be noted that the polar organic layer 50 may have a surface roughness under a microscope.

Thereafter, a top or counter electrode 60 is formed on the polar organic layer 50 to complete a photovoltaic cell. The top electrode 60 is preferably an opaque metal, such as Al, Ca/Al, Mg/Al, Cu, or Au. Typically in the art, this top electrode 60 is deposited by evaporation, though other deposition methods may be used. The thickness of the top electrode 60 may be, for example, between about 50 nm and 500 nm.

Although the simplified cross-section of FIG. 1 shows a polar organic layer 50 between the photoactive layer 40 and the top electrode 60, an embodiment of the invention may be implemented by providing the polar organic layer 50 between the photoactive layer 40 and the bottom electrode 20. Furthermore, two or more polar organic layers may be provided in the photovoltaic cell such that the photoactive layer 40 is sandwiched by these polar organic layers.

The invention is described in greater detail with reference to the following non-limiting examples.

### EXAMPLE 1

An ITO substrate was ultrasonicated in acetone and isopropyl alcohol respectively, blown dry with pure nitrogen gas, and finally dried in vacuum overnight. Thereafter, the ITO substrate was subjected to UV/ozone cleaning for 5 minutes, spin-coated with a film of PEDOT:PSS followed by 1 hour drying at 150° C. After cooled to room temperature, the substrate was spin-coated with a 1 wt % photoactive layer solution (P3HT:PCBM=1:1). The coated substrate was then slowly dried. Thereafter, the substrate was annealed at 140° C. for 10 minutes and then cooled. A polar organic layer was spin-coated at 6000 rpm for 30 seconds using a polyvinyl phenol (PVP) solution (0.01 wt % in methoxyethanol). Finally, calcium and aluminum were sequentially deposited on the polar organic layer by evaporation. The performance of the obtained photovoltaic cell was measured at 25° C. at 1000 W/m² and air mass 1.5 G from a solar simulator with results being shown in Table 1.

### EXAMPLE 2

The same procedure as in Example 1 was repeated, except that the polar organic layer was spin-coated at 4000 rpm for 30 seconds. The performance of the obtained photovoltaic cell was measured and the results are also listed in Table 1.

### EXAMPLE 3

The same procedure as in Example 1 was repeated, except that the polar organic layer was spin-coated at 2000 rpm for 30 seconds. The performance of the obtained photovoltaic cell was measured and the results are also listed in Table 1.

### COMPARATIVE EXAMPLE

The same procedure as in Example 1 was repeated, except that no polar organic layer was employed. The performance of the obtained photovoltaic cell was measured and the results are also listed in Table 1.

TABLE 1

| | Jsc | Voc | FF | PCE | coating parameter of |
|---|---|---|---|---|---|
| | (mA/cm²) | (mV) | (%) | (%) | polar organic layer |
| Example 1 | 16.7 | 0.582 | 55.8 | 5.42 | 6000 rpm/30 sec |
| Example 2 | 13 | 0.585 | 56.1 | 4.26 | 4000 rpm/30 sec |
| Example 3 | 11.4 | 0.588 | 61.8 | 4.14 | 2000 rpm/30 sec |
| Comp. Example | 11 | 0.553 | 50 | 3.05 | — |

*Jsc: short circuit current density
*Voc: open-circuit voltage
*FF: fill factor
*PCE: power conversion efficiency

As can be seen from Table 1, the photocurrent density (Jsc) of the photovoltaic cell of Example 1 was dramatically improved by about 50% compared to the counterpart in absence of the polar organic layer (Comparative Example), and the power conversion efficiency (PCE) was increased by almost 80%. The thickness of the polar polymer is expected to be decreasing with increasing spin rate. It is noted that the improvement in photocurrent density was diminished with increasing polar organic layer thickness.

### EXAMPLE 4

The same procedure as in Example 1 was repeated, except that the polar organic layer was spin-coated at 1000 rpm for 30 seconds.

### Adhesion Test

The samples of Example 4 and Comparative Example were evaluated for their adhesion using tape test. A Scotch Brand 3M tape was applied over the samples, and then rapidly peeled away. The amount of aluminum electrode remaining on the substrate gives a relative strength of adhesion. It was found that the sample of Example 4 was intact under the tape test, while about 83% aluminum electrode of Comparative Example was peeled off. This remarkable increase in electrode's adhesion can be attributed to the interfacial dipole generated by polar functionality of the polar organic layer.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A photovoltaic cell, comprising:
a first electrode;
a second electrode;
a photoactive layer between the first and second electrodes; and
a polar organic layer between the photoactive layer and at least one of the first and second electrodes.

2. The photovoltaic cell as claimed in claim 1, wherein the polar organic layer comprises a polar polymer.

3. The photovoltaic cell as claimed in claim 1, wherein the polar organic layer has a high dielectric constant (k) of above 3.

4. The photovoltaic cell as claimed in claim 1, wherein the polar organic layer has a thickness below 10 nm.

5. The photovoltaic cell as claimed in claim 1, having a photocurrent density at least 20% higher than that of a counterpart in absence of the polar organic layer.

6. The photovoltaic cell as claimed in claim 1, having a photocurrent density about 50% higher than that of a counterpart in absence of the polar organic layer.

7. The photovoltaic cell as claimed in claim 1, further comprising an additional polar organic layer such that the photoactive layer is sandwiched between the polar organic layer and the additional polar organic layer.

8. A photovoltaic cell, comprising:
a first electrode;
a second electrode;
a photoactive layer between the first and second electrodes; and
an organic layer between the photoactive layer and at least one of the first and second electrodes, wherein the organic layer comprises a surface opposite to the photoactive layer, possessing polar functionality pointing towards at least one of the electrodes.

9. The photovoltaic cell as claimed in claim 8, wherein the surface comprises at least one polar group of hydroxyl, carbonyl, carboxyl, mercapto, amino, halo, cyano, alkoxy, epoxy, and sulfonyl.

10. The photovoltaic cell as claimed in claim 8, wherein the surface possessing polar functionality is in contact with at least one of the electrodes.

11. The photovoltaic cell as claimed in claim 8, wherein the organic layer comprises a polar polymer.

12. The photovoltaic cell as claimed in claim 8, wherein the organic layer has a high dielectric constant (k) of above 3.

13. The photovoltaic cell as claimed in claim 8, wherein the organic layer has a thickness below 10 nm.

14. The photovoltaic cell as claimed in claim 8, having a photocurrent density at least 20% higher than that a counterpart in absence of the organic layer.

15. The photovoltaic cell as claimed in claim 8, having a photocurrent density about 50% higher than that a counterpart in absence of the organic layer.

16. The photovoltaic cell as claimed in claim 9, further comprising an additional organic layer such that the photoactive layer is sandwiched between the organic layer and the additional organic layer.
